(19) United States
(12) Patent Application Publication
(10) Pub. No.: US 2013/0320494 A1
(43) Pub. Date: Dec. 5, 2013

(54) METAL FINGER CAPACITORS WITH HYBRID METAL FINGER ORIENTATIONS IN STACK WITH UNIDIRECTIONAL METAL LAYERS

(71) Applicant: QUALCOMM INCORPORATED, San Diego, CA (US)

(72) Inventors: John J. Zhu, San Diego, CA (US); PR Chidambaram, San Diego, CA (US); Lixin Ge, San Diego, CA (US); Bin Yang, San Diego, CA (US); Jihong Choi, San Diego, CA (US)

(73) Assignee: QUALCOMM Incorporated, San Diego, CA (US)

(21) Appl. No.: 13/721,089

(22) Filed: Dec. 20, 2012

Related U.S. Application Data
(60) Provisional application No. 61/654,194, filed on Jun. 1, 2012.

(51) Int. Cl. H01L 49/02

(52) U.S. Cl. CPC H01L 28/40
USPC 257/532; 438/396

(57) ABSTRACT

A semiconductor die having a plurality of metal layers, including a set of metal layers having a preferred direction for minimum feature size. The set of metal layers are such that adjacent metal layers have preferred directions orthogonal to one another. Finger capacitors formed in the set of metal layers are such that a finger capacitor formed in one metal layer has a finger direction parallel to the preferred direction of that metal layer. In bidirectional metal layers, capacitor fingers may be in either direction.

### CLAIM OF PRIORITY UNDER 35 U.S.C. §119

The present Application for Patent claims priority to Provisional Application No. 61/654,194 entitled “METAL FINGER CAPACITORS WITH HYBRID METAL FINGER ORIENTATIONS IN STACK WITH UNIDIRECTIONAL METAL LAYERS” filed Jun. 1, 2012, and assigned to the assignee hereof and hereby expressly incorporated by reference herein.

### FIELD OF DISCLOSURE

The present invention relates to semiconductor fabrication, and more particularly to the fabrication of metal-oxide-metal (or more generally metal-dielectric-metal) finger capacitors.

### BACKGROUND

A common type of capacitor configuration for integrated circuits is the metal-oxide-metal finger capacitor, where the two plates of the capacitor comprise fingers that are interlaced (interdigitated) with one another. In many applications, it is desirable for integrated circuits to make use of high-density finger capacitors. That is, it is desirable for a finger capacitor having some given capacitance to occupy the least amount of area on a semiconductor die.

### SUMMARY

Embodiments of the invention are directed to systems and method for metal-oxide-metal finger capacitors.

In an embodiment, a semiconductor die includes a first finger capacitor fabricated in a first metal layer having a first preferred direction, where the finger direction of the first finger capacitor is parallel to the first preferred direction. The embodiment also includes a second finger capacitor fabricated in a second metal layer adjacent to the first metal layer. The second metal layer has a. second preferred direction orthogonal to the first preferred direction, and the finger direction of the second finger capacitor is parallel to the second preferred direction.

In another embodiment, the semiconductor die further includes a third finger capacitor fabricated in a third metal layer adjacent to the second metal layer. The third metal layer has a third preferred direction orthogonal to the second preferred direction, and the finger direction of the third finger capacitor is parallel to the third preferred direction,

In another embodiment, a first method includes depositing a bidirectional metal layer in a semiconductor die; patterning the bidirectional metal layer to form a capacitor; depositing a first unidirectional metal layer in the semiconductor die adjacent to the bidirectional metal layer, the first unidirectional metal layer having a first preferred direction; patterning the first unidirectional metal layer to form a first capacitor, the first capacitor comprising interdigitated fingers in a direction parallel to the first preferred direction; depositing a second unidirectional metal layer in the semiconductor die adjacent to the first unidirectional metal layer, the second unidirectional metal layer having a second preferred direction orthogonal to the first preferred direction; and patterning the second unidirectional metal layer to form a second capacitor, the second capacitor comprising interdigitated fingers in a direction parallel to the second preferred direction.

In another embodiment, the method further includes depositing a third unidirectional metal layer in the semiconductor die adjacent to the second unidirectional metal layer, the third unidirectional metal layer having a third preferred direction orthogonal to the second preferred direction; and patterning the third unidirectional metal layer to form a third capacitor, the third capacitor comprising interdigitated fingers in a direction parallel to the third preferred direction.

In another embodiment, a second method includes means for depositing a bidirectional metal layer in a semiconductor die; means for patterning the bidirectional metal layer to form a capacitor; means for depositing a first unidirectional metal layer in the semiconductor die adjacent to the bidirectional metal layer, the first unidirectional metal layer having a first preferred direction; means for patterning the first unidirectional metal layer to form a first capacitor, the first capacitor comprising interdigitated fingers in a direction parallel to the first preferred direction; means for depositing a second unidirectional metal layer in the semiconductor die adjacent to the first unidirectional metal layer, the second unidirectional metal layer having a second preferred direction orthogonal to the first preferred direction; and means for patterning the second unidirectional metal layer to form a second capacitor, the second capacitor comprising interdigitated fingers in a direction parallel to the second preferred direction.

In another embodiment, the second method further includes means for depositing a third unidirectional metal layer in the semiconductor die adjacent to the second unidirectional metal layer, the third unidirectional metal layer having a third preferred direction orthogonal to the second preferred direction; and means for patterning the third unidirectional metal layer to form a third capacitor, the third capacitor comprising interdigitated fingers in a direction parallel to the third preferred direction.

In another embodiment, a communication device includes a semiconductor die, where the semiconductor die includes a first unidirectional metal layer formed in the semiconductor die, the first metal layer having a first preferred direction; a first capacitor fabricated in the first metal layer, the first capacitor comprising interdigitated fingers having a direction parallel to the first preferred direction; a second unidirectional metal layer formed in the semiconductor die and adjacent to the first metal layer, the second unidirectional metal layer having a second preferred direction orthogonal to the first preferred direction; and a second capacitor fabricated in the second metal layer, the second capacitor comprising interdigitated fingers having a direction parallel to the second preferred direction.

In another embodiment, the semiconductor die in the communication device further includes a third unidirectional metal layer formed in the semiconductor die and adjacent to the second unidirectional metal layer, the third unidirectional metal layer having a third preferred direction orthogonal to the second preferred direction; and a third capacitor fabricated in the third unidirectional metal layer, the third capacitor comprising interdigitated fingers having a direction parallel to the third preferred direction.

In another embodiment, a third method includes a step of depositing a bidirectional metal layer in a semiconductor die; a step of patterning the bidirectional metal layer to form a capacitor; a step of depositing a first unidirectional metal layer in the semiconductor die adjacent to the bidirectional metal layer, the first unidirectional metal layer having a first preferred direction; a step of patterning the first unidirectional metal layer to form a first capacitor, the first capacitor comprising interdigitated fingers in a direction parallel to the first preferred direction; a step of depositing a second unidirectional metal layer in the semiconductor die adjacent to the first unidirectional metal layer, the second unidirectional metal layer having a second preferred direction orthogonal to the first preferred direction; and a step of patterning the second unidirectional metal layer to form a second capacitor, the second capacitor comprising interdigitated fingers in a direction parallel to the second preferred direction.

In another embodiment, the third method further includes a step of depositing a third unidirectional metal layer in the semiconductor die adjacent to the second unidirectional metal layer, the third unidirectional metal layer having a third preferred direction orthogonal to the second preferred direction; and a step of patterning the third unidirectional metal layer to form a third capacitor, the third capacitor comprising interdigitated fingers in a direction parallel to the third preferred direction.

### BRIEF DESCRIPTION OF THE DRAWINGS

The accompanying drawings are presented to aid in the description of embodiments of the invention and are provided solely for illustration of the embodiments and not limitation thereof.

FIG. 1 is an abstraction of semiconductor dice with metal-oxide-metal finger capacitors according to embodiments.

FIG. 2 illustrates the direction of a metal-oxide-metal finger capacitor according to an embodiment.

FIG. 3 illustrates the direction of a metal-oxide-metal finger capacitor according to an embodiment.

FIG. 4 illustrates a method according to an embodiment.

FIG. 5 illustrates a cellular phone network in which an embodiment may find application.

FIG. 6 illustrates a simplified abstraction of a mobile platform that may find application in FIG. 5 for which an embodiment may find application.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a. computing device. Specific circuits (e.g., application specific integrated circuits (ASICs)), program instructions being executed by one or more processors, or a combination of both, may perform the various actions described herein. Additionally, the sequences of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

In semiconductor fabrication, some metal layers within a semiconductor die (chip) are fabricated such that their smallest feature size is available in only one direction. For example, with an 80 nm pitch metal process in which single patterning lithography is used for a metal layer, the smallest trace width and spacing of 40 nm is available in only one direction along the plane of the metal layer. This direction is sometimes called the preferred direction of the metal layer. In a direction orthogonal to the preferred direction, the smallest trace width and spacing is 80 nm for this particular example.

For some process technologies, there is no preferred direction in a metal layer. For example, in a 90 nm metal pitch process technology utilizing single patterning lithography, the smallest trace width and spacing are each 45 nm, regardless of direction along the plane of the metal layer. For a 64 nm process technology utilizing double patterning lithography, the smallest trace width and spacing are each 32 nm, regardless of direction.

A metal layer having a preferred direction may be referred to as being unidirectional, and a metal layer having no preferred direction may be referred to as bidirectional.

In manufacturing an integrated circuit with multiple metal layers, it is common practice for the lower metal layers to be bidirectional, and for the higher metal layers to be unidirectional. For example, in an integrated circuit chip employing six metal layers, the first three lowest metal layers may be bidirectional, and the three upper metal layers may be unidirectional.

It is a common design practice for adjacent unidirectional metal layers to have their preferred directions orthogonal to one another. Having adjacent layers with orthogonal preferred directions allows for higher density placement for the routing interconnects. Accordingly, for adjacent metal layers that are unidirectional, it is preferable in many cases to alternate the direction of metal fingers to be aligned to the preferred direction of their respective metal layer.

The term adjacent when referring to a first layer and a second layer is to be interpreted to mean that the first and second layers are formed in a semiconductor die such that there is no other metal layer formed between them.

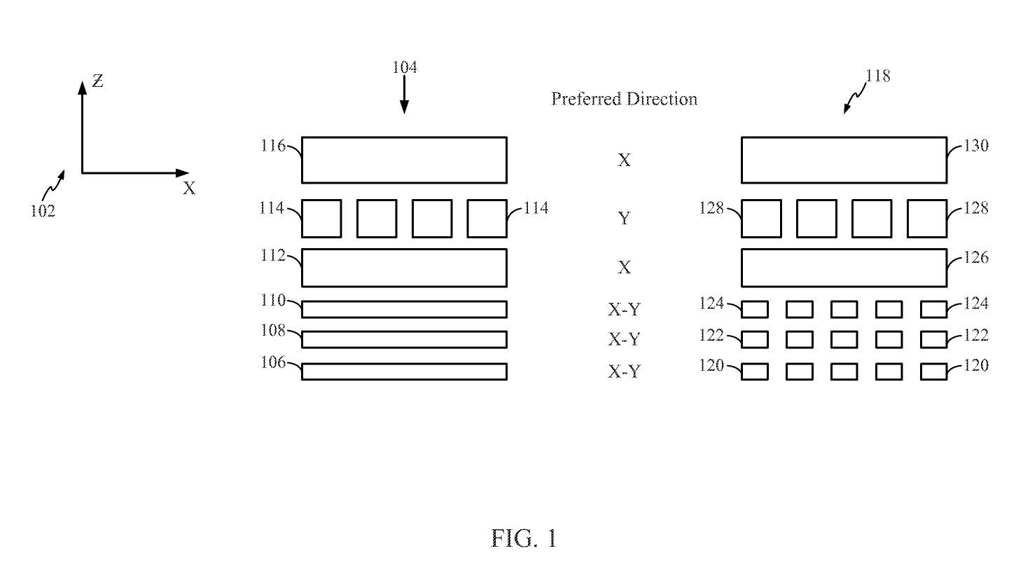

FIG. 1 illustrates the direction of metal-oxide-metal (MOM) finger capacitors in an integrated circuit die comprising six metal layers. More generally, embodiments may be understood to include metal-dielectric-metal finger capacitors, but for ease of discussion reference is made to MOM finger capacitors. For purposes of describing the embodiments, the coordinate system 102 provides a reference, where the X-axis and Z-axis lie in the plane of the illustration, and the Y-axis (not shown) points into the plane of the illustration.

In FIG. 1, a simplified abstraction of a semiconductor die, labeled 104, comprises six metal layers. MOM finger capacitors 106, 108, 110, 112, 114, and 116 are formed in these metal layers. For ease of discussion, the numeric label for a MOM finger capacitor will also be used when referring the metal layer in which the MOM finger capacitor is formed. It will be clear from context whether a metal layer or a capacitor is being referred to. Continuing with this naming convention, the first three metal layers 106, 108, and 110 are bidirectional; the top three metal layers 112, 114, and 116 are unidirectional.

Another simplified abstraction of a semiconductor die, labeled 118 in FIG. 1, comprises six metal layers, with metal layers 120, 122, 124, 126, 128, and 130. The first three metal layers 120, 122, and 124 are bidirectional; the top three metal layers 126, 128, and 130 are unidirectional.

A coordinate axis letter is placed next to each unidirectional metal layer to indicate its preferred direction. The letter “X” is placed next to metal layers 112, 126, 116, and 130 to indicate that their preferred directions are along the X-axis. The letter “Y” is placed next to the metal layers 114 and 128 to indicate that their preferred directions are along the Y-axis. The combination of letters “X-Y” is placed next to metal layers 106, 108, 110, 120, 122, and 124 to indicate that they are bidirectional. The structures for the MOM finger capacitors 112, 114, 116, 126, 128, and 130 illustrated in FIG. 1 are shown thicker than the structures for the MOM finger capacitors 106, 108, 110, 120, 122, and 124 to serve as a reminder that the process technology for the top three metal layers has a larger feature size than that of the bottom three metal layers.

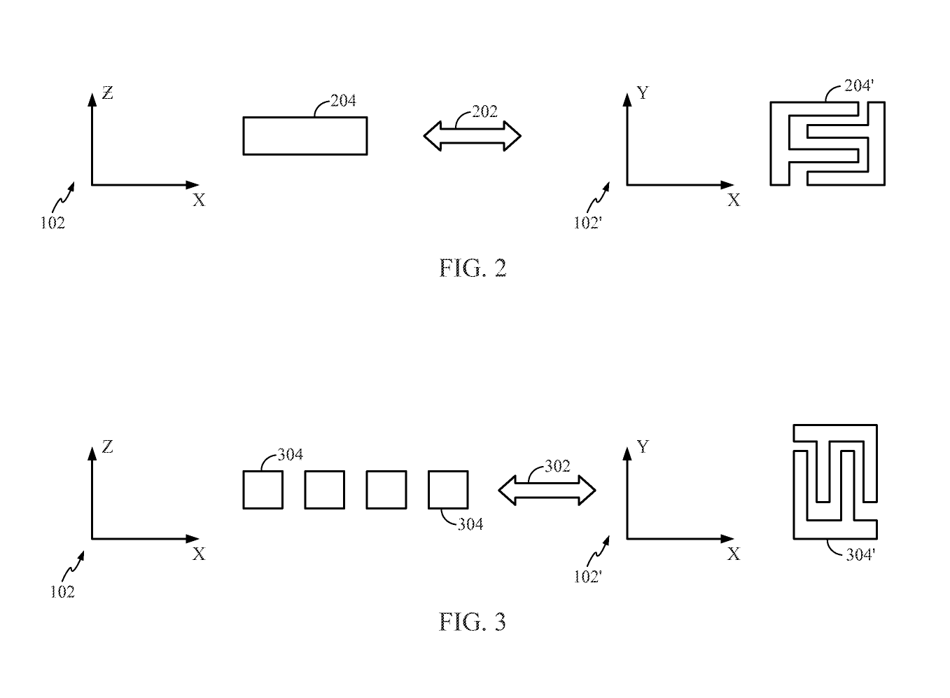

FIGS. 2 and 3 illustrate in more detail the direction of the MOM finger capacitors in FIG. 1. To the left of the equivalence arrow 202 in FIG. 2 is the coordinate system 102 and a simplified cross-sectional view of a MOM finger capacitor, labeled 204. To the right of the equivalence arrow 202 is the same coordinate system 102, but rotated so that the X-axis and Y-axis lie in the plane of the illustration, and the Z-axis (not shown) points out of the plane of the illustration. This rotated coordinate system is labeled 102′ to indicate that it is the same coordinate system labeled 102, but rotated as shown in FIG. 2. The MOM finger capacitor abstracted by the structure 204 now appears as the structure labeled 204′, presenting a simplified plan view of the MOM finger capacitor. The equivalence arrow 202 merely serves as an indicator that the structure abstracted in that portion of FIG. 2 to the left of equivalence arrow 202 is the same as the structure abstracted in that portion of FIG. 2 to the right of the equivalence arrow 202.

Note that the direction of the fingers for the MOM capacitor illustrated in FIG. 2 is along the X-axis. Accordingly, the illustration of FIG. 2 serves as a guide for the direction of the MOM finger capacitors 112, 116, 126, and 130, where the fingers for each of these capacitors are directed along the X-axis.

Referring now to FIG. 3, to the left of the equivalence arrow 302 is a simplified cross-sectional view of a MOM finger capacitor, labeled 304. To the right of the equivalence arrow 302 is the same MOM finger capacitor, but abstracted by the structure labeled 304′, presenting a simplified plan view of the MOM finger capacitor 304. Just as for the equivalence arrow 202, the equivalence arrow 302 merely serves as an indicator of the equivalence of the portions of FIG. 3 to the left and right side of the equivalence arrow 302.

Note that the direction of the fingers for the MOM capacitor illustrated in FIG. 3 is along the Y-axis. Accordingly, the direction of the MOM finger capacitors 114 and 128 is such that the fingers for each of these capacitors are directed along the Y-axis.

In light of the above discussion regarding capacitor direction or orientation, for the embodiments illustrated in FIG. 1, the MOM finger capacitors formed in a. unidirectional metal layer have their fingers in the same direction as the preferred direction. In this way, the width of each finger and the spacing between each finger may take advantage of the preferred direction so as to have the minimum feature size, leading to a higher capacitor density. For the bidirectional metal layers, the finger capacitors may have either direction.

Accordingly, for unidirectional metal layers in which the preferred directions for adjacent metal layers are orthogonal to one another, the directions of finger capacitors in adjacent layers will be orthogonal to one another.

By depositing unidirectional metal layers with preferred directions for adjacent layers orthogonal to each other, efficient routing is achieved, where interdigitated finger capacitors formed in the unidirectional metal layers have their fingers parallel to the preferred directions.

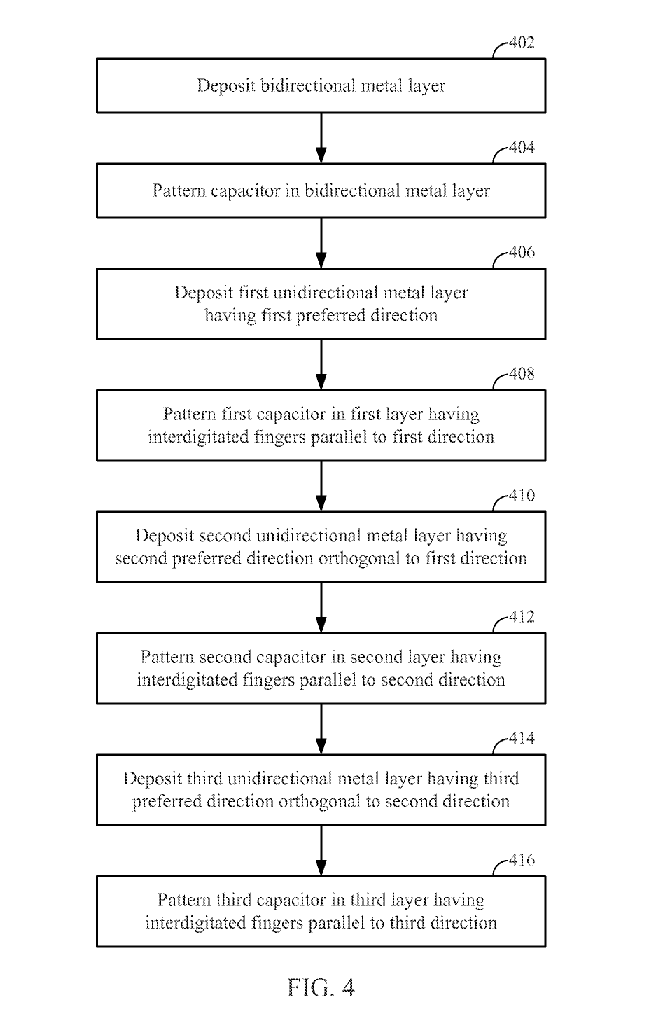

FIG. 4 illustrates a method according to an embodiment. Referring to box 402, a bidirectional metal layer is deposited on a semiconductor die. Standard techniques for deposition may be utilized. Lithographic patterning of the bidirectional metal layer may be used to form interdigitated finger capacitors (404). The steps indicated in boxes 402 and 404 may be repeated so that multiple adjacent bidirectional metallic layers may be deposited with multiple capacitors patterned thereon.

Referring to box 406, a first unidirectional metal layer is deposited adjacent to the topmost bidirectional metal layer, having a first preferred direction. The first unidirectional metal layer is patterned to form a first capacitor, where the first capacitor has interdigitated fingers parallel to the first preferred direction (408). As indicated in blocks 410, 412, 414, and 416, the pair of steps performed in boxes 406 and 408 are repeated except were the preferred directions of adjacent unidirectional layers are orthogonal to each other, where a finger capacitor in unidirectional metal layer has interdigitated fingers in a direction parallel to the preferred direction of its corresponding unidirectional metal layer.

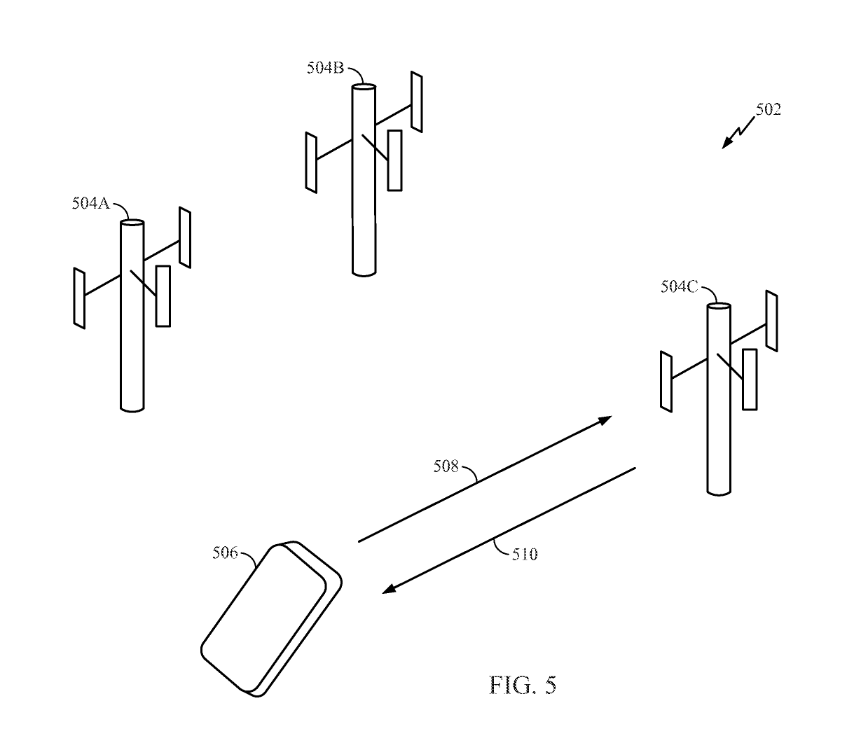

Embodiments may find widespread application in numerous systems, such as a communication network. For example, FIG. 5 illustrates a cellular phone network 502 comprising base stations 504A, 504B, and 504C. FIG. 5 shows a communication device, labeled 506, which may be a mobile cellular communication device such as a smart phone, a tablet, cellular phone, or some other kind of communication device suitable for a cellular phone network. The communication device 506 need not be mobile. In the particular example of FIG. 5, communication device 506 is located within the cell associated with the base station 504C. Arrows 508 and 510 pictorially represent the uplink channel and the downlink channel, respectively, by which communication device 506 communicates with base station 504C.

Embodiments may be used in data processing systems associated with communication device 506, or with base station 504C, or both, for example. FIG. 5 illustrates only one application among many in which the embodiments described herein may be employed.

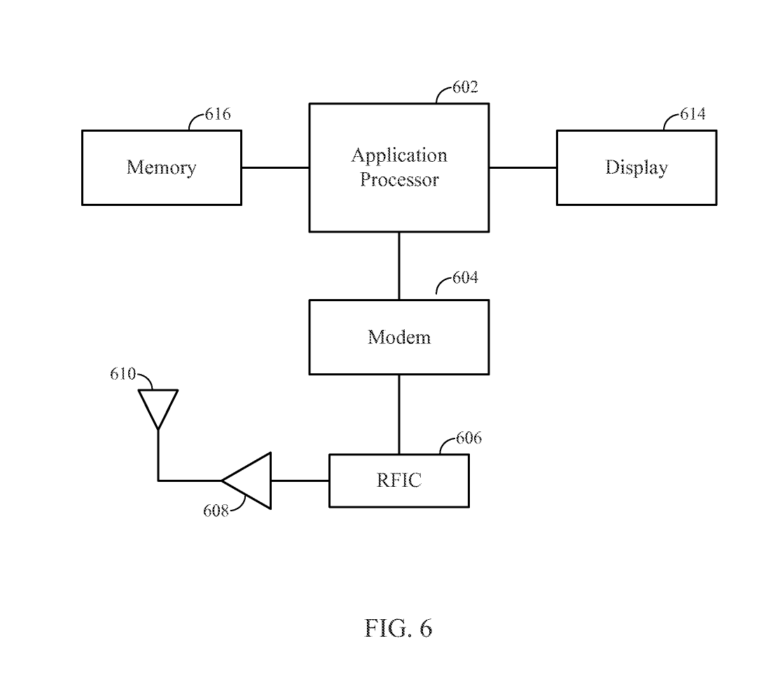

FIG. 6 illustrates a simplified abstraction of a mobile platform that may find application in the communication device 506. Shown in FIG. 6 are an application processor 602, a modem 604, a radio frequency integrated circuit (RFIC) 606, a power amplifier 608, a radio frequency (RF) antenna 610, a display 614, and a memory 616. The memory 616 may be a memory hierarchy. For simplicity, not all components typically found in a mobile platform are illustrated in FIG. 6.

Embodiments may find application in semiconductor dice used in the components illustrated in FIG. 6, such as for example the application processor 602 and modem 604.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A semiconductor die comprising:
a first unidirectional metal layer formed in the semiconductor die, the first unidirectional metal layer having a first preferred direction;
a first capacitor fabricated in the first unidirectional metal layer, the first capacitor comprising interdigitated fingers having a direction parallel to the first preferred direction;
a second unidirectional metal layer formed in the semiconductor die and adjacent to the first unidirectional metal layer, the second unidirectional metal layer having a second preferred direction orthogonal to the first preferred direction;
a second capacitor fabricated in the second unidirectional metal layer, the second capacitor comprising interdigitated fingers having a direction parallel to the second preferred direction.

2. The semiconductor die of claim 1, further comprising:
a third unidirectional metal layer formed in the semiconductor die and adjacent to the second unidirectional metal layer, the third unidirectional metal layer having a third preferred direction orthogonal to the second preferred direction;
a third capacitor fabricated in the third unidirectional metal layer, the third capacitor comprising interdigitated fingers having a direction parallel to the third preferred direction.

3. The semiconductor die of claim 2, further comprising:
a fourth bidirectional metal layer formed in the semiconductor die and adjacent to the first unidirectional metal layer;
a fourth capacitor fabricated in the fourth bidirectional metal layer, the fourth capacitor comprising interdigitated fingers having a direction parallel to the first preferred direction.

4. The semiconductor die of claim 2, further comprising:
a fourth bidirectional metal layer formed in the semiconductor die and adjacent to the first unidirectional metal layer;
a fourth capacitor fabricated in the fourth bidirectional metal layer, the fourth capacitor comprising interdigitated fingers having a direction orthogonal to the first preferred direction.

5. The semiconductor die of claim 2, wherein the first, second, and third capacitors are each metal-oxide-metal finger capacitors.

6. A method comprising:
depositing a bidirectional metal layer in a semiconductor die;
patterning the bidirectional metal layer to form a capacitor;
depositing a first unidirectional metal layer in the semiconductor die adjacent to the bidirectional metal layer, the first unidirectional metal layer having a first preferred direction;
patterning the first unidirectional metal layer to form a first capacitor, the first capacitor comprising interdigitated fingers in a direction parallel to the first preferred direction;
depositing a second unidirectional metal layer in the semiconductor die adjacent to the first unidirectional metal layer, the second unidirectional metal layer having a second preferred direction orthogonal to the first preferred direction;
patterning the second unidirectional metal layer to form a second capacitor, the second capacitor comprising interdigitated fingers in a direction parallel to the second preferred direction.

7. The method of claim 6, further comprising:
depositing a third unidirectional metal layer in the semiconductor die adjacent to the second unidirectional metal layer, the third unidirectional metal layer haying a third preferred direction orthogonal to the second preferred direction;
patterning the third unidirectional metal layer to form a third capacitor, the third capacitor comprising interdigitated fingers in a direction parallel to the third preferred direction.

8. The method of claim 7, wherein the capacitor formed in the bidirectional metal layer comprises interdigitated fingers parallel to the first preferred direction.

9. The method of claim 7, wherein the capacitor formed in the bidirectional metal layer comprises interdigitated fingers in a direction orthogonal to the first preferred direction.

10. The method of claim 7, wherein the first, second, and third capacitors are each metal-oxide-metal finger capacitors.

11. A method comprising:
means for depositing a bidirectional metal layer in a semiconductor die;
means for patterning the bidirectional metal layer to form a capacitor;
means for depositing a first unidirectional metal layer in the semiconductor die adjacent to the bidirectional metal layer, the first unidirectional metal layer having a first preferred direction;
means for patterning the first unidirectional metal layer to form a first capacitor, the first capacitor comprising interdigitated fingers in a direction parallel to the first preferred direction;
means for depositing a second unidirectional metal layer in the semiconductor die adjacent to the first unidirectional metal layer, the second unidirectional metal layer having a second preferred direction orthogonal to the first preferred direction;
means for patterning the second unidirectional metal layer to form a second capacitor, the second capacitor comprising interdigitated fingers in a direction parallel to the second preferred direction.

12. The method of claim 11, further comprising:
means for depositing a third unidirectional metal layer in the semiconductor die adjacent to the second unidirectional metal layer, the third unidirectional metal layer having a third preferred direction orthogonal to the second preferred direction;
means for patterning the third unidirectional metal layer to form a third capacitor, the third capacitor comprising interdigitated fingers in a direction parallel to the third preferred direction.

13. The method of claim 12, wherein the capacitor formed in the bidirectional metal layer comprises interdigitated fingers parallel to the first preferred direction.

14. The method of claim 12, wherein the capacitor formed in the bidirectional metal layer comprises interdigitated fingers in a direction orthogonal to the first preferred direction.

15. The method of claim 12, wherein the first, second, and third capacitors are each metal-oxide-metal finger capacitors.

16. A communication device comprising a semiconductor die, the semiconductor die comprising:
a first unidirectional metal layer formed in the semiconductor die, the first unidirectional metal layer having a first preferred direction;
a first capacitor fabricated in the first unidirectional metal layer, the first capacitor comprising interdigitated fingers having a direction parallel to the first preferred direction;
a second unidirectional metal layer formed in the semiconductor die and adjacent to the first unidirectional metal layer, the second unidirectional metal layer having a second preferred direction orthogonal to the first preferred direction;
a second capacitor fabricated in the second unidirectional metal layer, the second capacitor comprising interdigitated fingers having a direction parallel to the second preferred direction.

17. The communication device of claim 16, the semiconductor die further comprising:
a third unidirectional metal layer formed in the semiconductor die and adjacent to the second unidirectional metal layer, the third unidirectional metal layer haying a third preferred direction orthogonal to the second preferred direction;
a third capacitor fabricated in the third unidirectional metal layer, the third capacitor comprising interdigitated fingers having a direction parallel to the third preferred direction.

18. The communication device of claim 17, the semiconductor die further comprising:
a fourth bidirectional metal layer formed in the semiconductor die and adjacent to the first unidirectional metal layer;
a fourth capacitor fabricated in the fourth bidirectional metal layer, the fourth capacitor comprising interdigitated fingers parallel to the first preferred direction.

19. The communication device of claim 17, the semiconductor die further comprising:
a fourth bidirectional metal layer formed in the semiconductor die and adjacent to the first unidirectional metal layer;
a fourth capacitor fabricated in the fourth bidirectional metal layer, the fourth capacitor comprising interdigitated fingers having a direction orthogonal to the first preferred direction.

20. The communication device of claim 17, wherein the first, second, and third capacitors are each metal-oxide-metal finger capacitors.

21. The communication device of claim 16, wherein the communication device is selected from the group consisting of a cellular phone and a base station.

22. A method comprising:
step of depositing a bidirectional metal layer in a semiconductor die;
step of patterning the bidirectional metal layer for form a capacitor;
step of depositing a first unidirectional metal layer in the semiconductor die adjacent to the bidirectional metal layer, the first unidirectional metal layer having a first preferred direction;
step of patterning the first unidirectional metal layer to form a first capacitor, the first capacitor comprising interdigitated fingers in a direction parallel to the first preferred direction;
step of depositing a second unidirectional metal layer in the semiconductor die adjacent to the first unidirectional metal layer, the second unidirectional metal layer having a second preferred direction orthogonal to the first preferred direction;
step of patterning the second unidirectional metal layer to form a second capacitor, the second capacitor comprising interdigitated fingers in a direction parallel to the second preferred direction.

23. The method of claim 22, further comprising:
step of depositing a third unidirectional metal layer in the semiconductor die adjacent to the second unidirectional metal layer, the third unidirectional metal layer having a third preferred direction orthogonal to the second preferred direction;
step of patterning the third unidirectional metal layer to form a third capacitor, the third capacitor comprising interdigitated fingers in a direction parallel to the third preferred direction.

24. The method of claim 23, wherein the capacitor formed in the bidirectional metal layer comprises interdigitated fingers parallel to the first preferred direction.

25. The method of claim 23, wherein the capacitor formed in the bidirectional metal layer comprises interdigitated fingers in a direction orthogonal to the first preferred direction.

26. The method of claim 23, wherein the first, second, and third capacitors are each metal-oxide-metal finger capacitors.
